(19) United States
(12) Patent Application Publication
(10) Pub. No.: US 2012/0289036 A1
(43) Pub. Date: Nov. 15, 2012

(54) SURFACE DOSE RETENTION OF DOPANTS BY PRE-AMORPHIZATION AND POST IMPLANT PASSIVATION TREATMENTS

(75) Inventors: Kartik Santhanam, Milpitas, CA (US); Manoj Vellaikal, Sunnyvale, CA (US); Yen B. Ta, Pomona, CA (US); Matthew D. Scotney-Castle, Morgan Hill, CA (US); Peter I. Porshnev, Poway, CA (US)

(73) Assignee: APPLIED MATERIALS, INC., Santa Clara, CA (US)

(21) Appl. No.: 13/449,180

(22) Filed: Apr. 17, 2012

Related U.S. Application Data
(60) Provisional application No. 61/485,040, filed on May 11, 2011.

(51) Int. Cl. H01L 21/265

(52) U.S. Cl. 438/513; 438/532; 257/E21.334

(57) ABSTRACT

The invention generally relates to pre-implant and post-implant treatments to promote the retention of dopants near the surface of an implanted substrate. The pre-implant treatments include forming a plasma from an inert gas and implanting the inert gas into the substrate to render an upper portion of the substrate amorphous. The post-implant treatment includes forming a passivation layer on the upper surface of the substrate after doping the substrate in order to retain the dopant during a subsequent activation anneal.

### CROSS-REFERENCE TO RELATED APPLICATIONS

This application claims benefit of U.S. Provisional Patent Application Ser. No. 61/485,040, filed May 11, 2011, which is herein incorporated by reference.

### BACKGROUND OF THE INVENTION

1. Field of the Invention

Embodiments of the invention generally relate to methods of implanting dopants in semiconductor materials.

2. Description of the Related Art

The formation of semiconductor junctions on the surface of a semiconductor wafer is generally carried out by implantation of ions of either acceptor or donor impurity species into the surface. The implanted semiconductor wafer surface is then annealed at elevated temperatures in order to cause the implanted species to be substituted for silicon atoms within the crystal lattice, which is commonly known as “activating” the implanted species. The conductance of the implanted region of the semiconductor is determined by the junction depth and the volume concentration of the thermally activated implanted dopant species.

A higher conductance of the implanted region is generally desirable in order to reduce the contact resistance between the implanted region and a metal contact layer subsequently deposited thereon. Thus, it is desirable to have a relatively large concentration of the implanted dopant species in the junction region. However, during the anneal process to activate the dopant species, the dopant species often sublimates from the junction region and diffuses from the semiconductor wafer. Due to the removal of the dopant species from the junction region, the conductance of the junction region is decreased, and the contact resistance with the subsequently deposited metal contact is increased. The increased contact resistance undesirably reduces device performance.

Therefore, there is a need for a pre-implant and post-implant treatment to maintain surface dopant concentrations.

### SUMMARY OF THE INVENTION

The invention generally relates to pre-implant and post-implant treatments to promote the retention of dopants near the surface of an implanted substrate. The pre-implant treatments include forming a plasma from an inert gas and implanting the inert gas into the substrate to render an upper portion of the substrate amorphous. The post-implant treatment includes forming a passivation layer on the upper surface of the substrate after doping the substrate in order to retain the dopant during a subsequent activation anneal.

In one embodiment, a method of doping a substrate comprises generating a plasma from an inert gas, and implanting atoms of the inert gas into the substrate to render a portion of the substrate amorphous. A plasma is then generated from a dopant gas, and atoms of the dopant gas are implanted into the substrate. The substrate is then exposed to a passivating gas to passivate the upper surface of the substrate, and the substrate is annealed.

In another embodiment, a method of doping a substrate comprises generating a plasma from an inert gas comprising argon, helium, or hydrogen. Atoms of the inert gas are the implanted into a polysilicon substrate to form an amorphous silicon layer on the upper surface of the polysilicon substrate. A plasma is then generated from a p-type dopant gas, and atoms of the p-type dopant gas are implanted into the substrate. The polysilicon substrate is then exposed to a passivating gas to passivate the upper surface of the substrate, and the polysilicon substrate is annealed.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a perspective view of a partial section of a plasma immersion ion implant chamber.

FIG. 2 is a flow diagram illustrating a method of implanting a substrate including a pre-implant and a post-implant treatment.

FIG. 3 is a graph of secondary ion mass spectroscopy data comparing a doped substrate of the present invention to a doped substrate without any pre-implant or post-implant treatments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The invention generally relates to pre-implant and post-implant treatments to promote the retention of dopants near the surface of an implanted substrate. The pre-implant treatments include forming a plasma from an inert gas and implanting the inert gas into the substrate to render an upper portion of the substrate amorphous. The post-implant treatment includes forming a passivation layer on the upper surface of the substrate after doping the substrate in order to retain the dopant during a subsequent activation anneal.

Embodiments of the present invention may be practiced in an implant chamber, such as a P3i™ chamber, available from Applied Materials, Inc., of Santa Clara, Calif. It is contemplated that other implant chambers, including those produced by other manufacturers, may benefit from embodiments described herein.

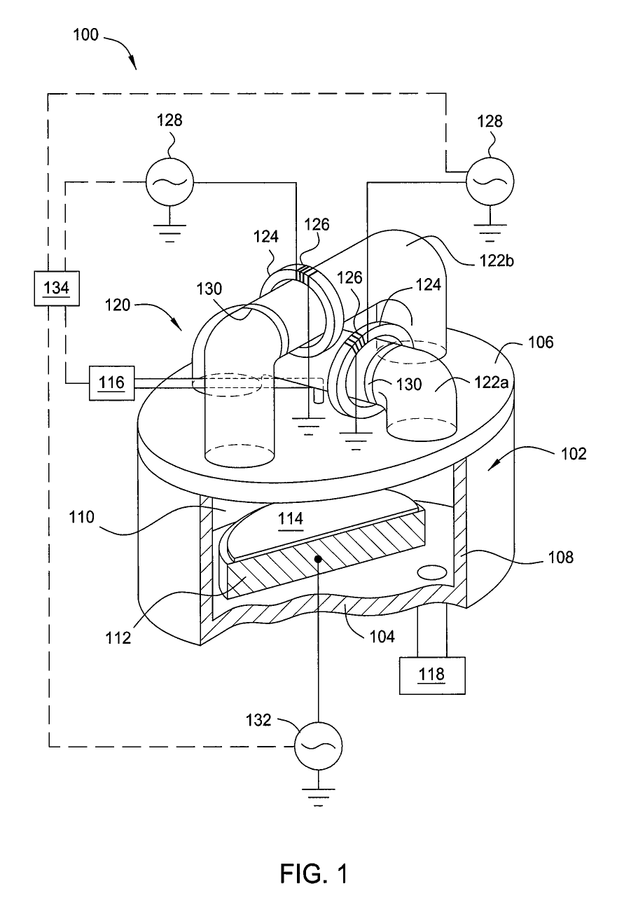

FIG. 1 is a perspective view of a partial section of a plasma immersion ion implant chamber 100. The chamber 100 includes a chamber body 102 having a bottom 104, a top 106, and a side wall 108 enclosing a process region 110. A substrate support assembly 112 is supported on the bottom 104 of the chamber body 102 and is adapted to receive a substrate 114 for processing. A gas distribution plate (not shown) is coupled to the underside of the top 106 of the chamber body 102 facing the substrate support assembly 112. A process gas source 116 is coupled to the gas distribution plate to supply process gases to the process region 110 for processes performed on the substrate 114. A vacuum pump 118 is coupled to the bottom 104 of the chamber body 102 to remove the process gases from the process region 110.

The chamber 100 further includes a plasma source 120 positioned on the top 106. The plasma source 120 includes a pair of separate external reentrant conduits 122a, 122b mounted on the upper surface of the top 106 of the chamber body 102. Each external reentrant conduit 122a, 122b is a hollow tube of electrically conductive material interrupted by an insulating annular ring 130 that interrupts an otherwise continuous electrical path between each end of the external reentrant conduit 122a, 122b. A magnetically permeable torroidal core 124 is disposed around each of the external reentrant conduits 122a, 122b. Conductive coils 126 are disposed around the magnetically permeable torroidal cores 124 and are coupled to respective RF plasma source power generators 128. An RF plasma bias power generator 132 is connected to the substrate support assembly 112 to bias the substrate support assembly 112 and the substrate 114 positioned thereon. The RF plasma bias power generator 132 controls the ion energy at the surface of the substrate 114 using an impedance match circuit (not shown) connected to a controller 134.

Process gases are supplied from the process gas source 116 through the gas distribution plate into the process region 110. RF plasma source power generators 128 and the magnetically permeable torroidal cores 124 form an ionized gas in the external reentrant conduits 122a, 122b as process gases are circulated therethrough. The power of the RF plasma bias power generator 132 is controlled by the controller 134 at a selected level at which the ion energy dissociated from the process gases may be accelerated toward the substrate surface and implanted at a desired depth below the top surface of the substrate 114 at a desired ion concentration.

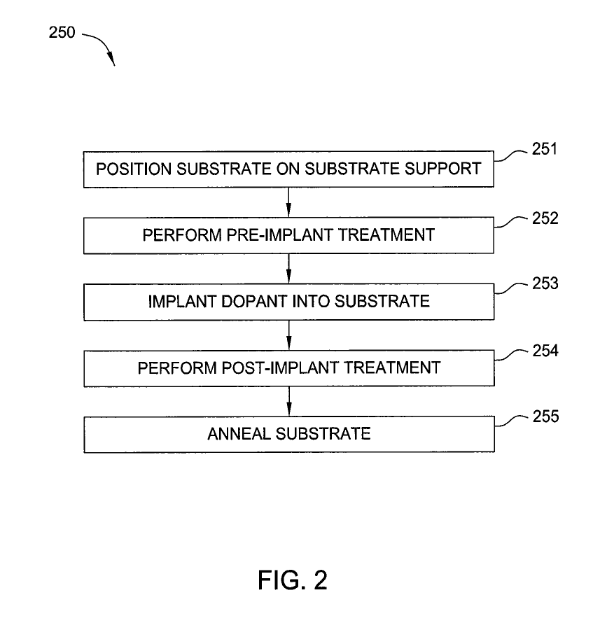

FIG. 2 is a flow diagram 250 illustrating a method of implanting a substrate including a pre-implant and a post-implant treatment. Flow diagram 250 begins at step 251, in which a substrate is positioned on a substrate support within an implant chamber, such as a plasma immersion ion implant chamber. The substrate is generally a polysilicon substrate, such as a silicon wafer. In step 252, the substrate is subjected to a pre-implant treatment process. The pre-implant treatment amorphizes (i.e., renders amorphous) an upper portion of the substrate to limit the dopant diffusion depth in a subsequent implant process (e.g., step 253). The pre-implant treatment process of step 252 includes exposing the substrate to a plasma of an inert gas, such as helium, and implanting the ionized species into the substrate to a desired depth and concentration.

The ionized species is implanted into the substrate to a concentration.within a range from about 1×10¹³ atoms per cubic centimeter to about 3×10¹⁵ atoms per cubic centimeter. The pre-implant ionized species is implanted to a higher concentration than that which would normally occur during a dry etch process used to remove native oxides (e.g., 1×10¹³ atoms per cubic centimeter). The relatively higher concentration of the pre-implant ionized species can be accomplished by maintaining a higher pressure within the implant chamber, by increasing flow of the inert gas to the implant chamber, or by increasing the substrate bias voltage applied during the pre-implant treatment process.

The relatively higher concentration of implanted species, such as greater than 9×10¹³ atoms per cubic centimeter, disrupts the silicon lattice of the polysilicon substrate and redistributes the silicon atoms during implantation. The implanted species alters the crystalline lattice of the silicon from polysilicon to amorphous silicon. The physical structure of the amorphous silicon prevents over penetration of subsequently implanted dopant species, thus resulting in a relatively higher concentration of dopant atoms near the surface of the substrate in the amorphous silicon layer.

The amorphous silicon layer generally has a thickness less than 200 angstroms, for example, about 100-200 angstroms. The thickness of the amorphous silicon layer can be adjusted by varying the bias applied to the substrate during the pre-treatment implant process. For example, a substrate bias of less than about 50 eV may be applied to implant the ionized species into the substrate to a depth between about 0 Å and about 100 Å from the substrate surface. Alternatively, the substrate bias of greater than about 50 eV may be applied to implant the ionized species to a depth greater than 100 Å from the substrate surface.

In step 253, after amorphizing the upper surface of the substrate, a dopant species, such as phosphorus or another p-type dopant, is implanted into the substrate. A process gas containing the dopant species is introduced to the process chamber, and the process gas is then ionized. The substrate is then biased, and the dopant species is accelerated towards the substrate and implanted into the amorphous layer on the upper surface of the substrate. The dopant may be implanted into the amorphous layer of the substrate to a dopant concentration of about 2×10²⁰ atoms per cubic centimeter to about 2×10²¹ atoms per cubic centimeter, or more.

After doping the substrate to a predetermined dopant concentration, a post-implant treatment is performed in step 254 to passivate the upper surface of the substrate. The upper surface of the substrate may be passivated by forming a passivation layer thereon. The passivation layer prevents the sublimation or removal of the dopant species of step 253 during a subsequent annealing process (e.g., step 255). During the passivation post-treatment process, the upper surface of the substrate is exposed to a passivating gas, such as oxygen or hydrogen, which passivates the exposed surface of the amorphous silicon located on the upper surface of the substrate. The passivating gas is generally introduced to the chamber at a flow rate of about 25 SCCM to about 500 SCCM. The partial pressure of the passivating gas and the temperature within the chamber can be adjusted to effect the desired amount of surface passivation. Generally, the passivation layer has a thickness less than 30 angstroms, for example, about 10 angstroms to about 20 angstroms.

During step 255, after passivation of the upper surface of the substrate, the substrate is annealed at a temperature of about 600 degrees Celsius to about 1300 degrees Celsius for about 0.5 seconds to about 1800 seconds. During the annealing process, the dopant implanted in step 253 is activated, while the dopant implanted during step 252 is sublimated from the substrate. The dopant implanted in step 252 is selectively sublimated from the substrate as compared to the dopant of step 253 due to the lower molecular weight and/or vapor pressure of the dopant of step 252.

Flow diagram 250 describes one embodiment for doping a substrate, however, other embodiments are also contemplated. Flow diagram 250 is described in relation to a polysilicon substrate, however, other types of substrates, including monocrystalline and amorphous silicon substrates may also benefit from embodiments described herein. When using an amorphous silicon substrate, it is contemplated that the pre-implant treatment may be omitted since the upper surface of the substrate is already amorphous.

Additionally, although step 251 is described as using helium, it is contemplated that other inert gases may be used, including argon and hydrogen. Furthermore, in one embodiment, it is contemplated that each of steps 251-255 occur in a single process chamber. In another embodiment, it is contemplated that steps 250-254 occur in a first process chamber, while step 255 occurs in a second process chamber. In yet another embodiment, it is contemplated that passivating gas of step 254 may be ionized. In such an embodiment, the substrate is generally not biased during the passivation process. In another embodiment, it is contemplated that the passivation layer may be removed using a wet clean subsequent to step 255.

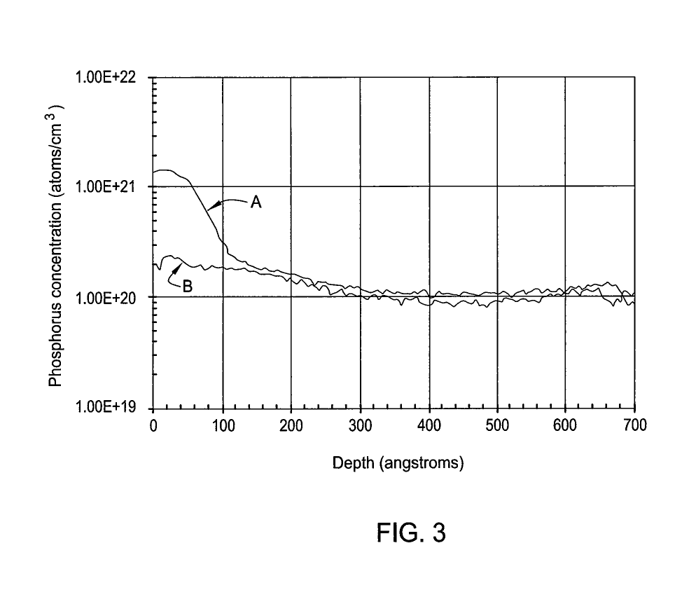

FIG. 3 is a graph of secondary ion mass spectroscopy data comparing a doped substrate of the present invention to a doped substrate without any pre-implant or post-implant treatments. Plot A illustrates the phosphorus dopant concentration within a polysilicon substrate subjected to both a pre-implant and post-implant treatment process, while plot B illustrates the phosphorus concentration within a polysilicon substrate subjected only to an implant process.

The substrate of plot A was subjected to a pre-implant treatment in which approximately the first 100 angstroms of the substrate were amorphized. The substrate was then implanted with phosphorus to a concentration of about 2×10²¹ atoms per cubic centimeter. Subsequently, the surface of the substrate was passivated, and the substrate was annealed. After annealing, the substrate of plot A maintained a dopant concentration greater than 1×10²¹ atoms per cubic centimeter near the surface of the substrate. The phosphorus concentration in the substrate of plot A gradually declines as the depth of the substrate increases, and has an average phosphorus concentration of about 1.5×10²⁰ atoms per cubic centimeter in the polysilicon portion of the substrate. Presence of the dopant in the polysilicon portion of the substrate can be attributed to migration of the dopant during annealing, and generally has a negligible effect on the performance of the final device due to the tenfold greater dopant concentration ear the surface of the substrate.

The substrate of plot B was not subjected to either a pre-implant or a post-implant treatment. The substrate of plot was doped with phosphorus to a concentration of about 2×10²¹ atoms per cubic centimeter, and then annealed. After annealing, the phosphorus concentration near the surface of the substrate, for example, the first 100 angstroms, was approximately 2×10²⁰ atoms per cubic centimeter. The phosphorus concentration at a depth between about 300 angstroms and about 700 angstroms averaged about 1×10²⁰ atoms per cubic centimeter. Thus, not only is the dopant concentration of the substrate of plot B lower near the surface than the substrate of plot A (resulting in increased contact resistance), but the overall concentration of phosphorus through the substrate of plot B is lower than that of the substrate of plot A. Therefore, not only do the pre-implant and post-implant treatments maintain a higher dopant concentration near the surface of the substrate, but the treatments also reduce the occurrence of sublimation of the dopant from the substrate, as illustrated by overall higher phosphorus concentration exhibited in plot A.

Benefits of the present invention include increased retention of dopants during implant processes. The dopant is desirably maintained near the surface of the substrate due to pre-implant and post-implant treatment processes, reducing contact resistance with a metal layer subsequently deposited thereon. Embodiments described herein are especially advantageous for n-type dopants where the vaporization temperature is often less than the annealing temperature, and the dopants would otherwise sublimate from the substrate absent the pre-implant and post-implant processes described herein.

While the foregoing is directed to embodiments of the present invention, other and further embodiments of the invention may be devised without departing from the basic scope thereof, and the scope thereof is determined by the claims that follow.

We claim:

1. A method of doping a substrate, comprising:
generating a plasma from an inert gas;
implanting atoms of the inert gas into the substrate to render a portion of the substrate amorphous;
generating a plasma from a dopant gas;
implanting atoms of the dopant gas into the substrate;
exposing the substrate to a passivating gas to passivate the upper surface of the substrate; and
annealing the substrate.

2. The method of claim 1, wherein the substrate comprises polysilicon.

3. The method of claim 2, wherein implanting atoms of the inert gas into the substrate comprises redistributing a portion of the polysilicon silicon to render it amorphous silicon.

4. The method of claim 2, wherein implanting atoms of the inert gas into the substrate comprises biasing the substrate.

5. The method of claim 1, wherein the inert gas is helium, argon, or hydrogen.

6. The method of claim 1, wherein the dopant is an n-type dopant.

7. The method of claim 6, wherein the dopant is phosphorus.

8. The method of claim 1, wherein the passivating gas is oxygen or hydrogen.

9. The method of claim 1, wherein the inert gas is implanted into the substrate to a concentration within a range from about 9×10¹³ atoms per cubic centimeter to about 3×10¹⁵ atoms per cubic centimeter.

10. A method of doping a substrate, comprising:
generating a plasma from an inert gas comprising argon, helium, or hydrogen;
implanting atoms of the inert gas into a polysilicon substrate to form an amorphous silicon layer on the upper surface of the polysilicon substrate;
generating a plasma from a p-type dopant gas;
implanting atoms of the p-type dopant gas into the polysilicon substrate;
exposing the substrate to a passivating gas to passivate the upper surface of the polysilicon substrate; and
annealing the polysilicon substrate.

11. The method of claim 10, wherein the amorphous silicon layer has a thickness less than 200 angstroms.

12. The method of claim 10, wherein exposing the substrate to a passivating gas comprises forming a passivation layer on the upper surface of the polysilicon substrate.

13. The method of claim 12, wherein the passivation layer has a thickness less than about 30 angstroms.

14. The method of claim 13, further comprising removing the passivation layer from the surface of the substrate after the annealing.

15. The method of claim 12, wherein annealing the substrate comprises sublimating from the substrate the implanted atoms of inert gas.
